(19) United States
(12) Patent Application Publication
(10) Pub. No.: US 2012/0299684 A1
(43) Pub. Date: Nov. 29, 2012

(54) TRANSFORMER WITH LOW EDDY CURRENT AND MAGNETIC HYSTERESIS LOSS AND MANUFACTURING METHOD THEREOF

(75) Inventor: Jong Keun Won, Bucheon-si (KR)

(73) Assignee: YOUNGSIN METAL INDUSTRIAL CO., LTD., Pyeongtaek-si, Gyeonggi-do (KR)

(21) Appl. No.: 13/575,529

(22) PCT Filed: Jan. 29, 2010
(86) PCT No.: PCT/KR2010/000554

§ 371 Date: Jul. 26, 2012

(51) Int. Cl. H01F 27/32; H05K 13/00

(52) U.S. Cl. 336/206; 29/602.1

(57) ABSTRACT

The present invention relates to a transformer with a low eddy current and magnetic hysteresis loss and a manufacturing method thereof. The transformer with the low eddy current and magnetic hysteresis loss comprises a core, a primary coil and a secondary coil, an insulating paper, and an insulation material, wherein the core is made of an amorphous material or ferrite, the insulating paper and the insulation material have low permittivity and a high insulation rate regardless of insulation class, an interlayer insulation thickness of the coils is maintained to be greater than 1 mm and smaller than 4 mm, and an insulation interval between the core and the coil is maintained to be greater than 5 mm and smaller than 10 mm.

### TECHNICAL FIELD

The present invention relates to a transformer with low eddy current and magnetic hysteresis losses and a manufacturing method thereof, and more particularly, to a transformer with low eddy current and magnetic hysteresis losses capable of preventing an insulation breakdown phenomenon of a transformer for an electrical device, thereby minimizing high heat, condensation, and streamer that occur in an electrode and a dielectric, and a manufacturing method thereof.

### BACKGROUND ART

A transformer is a kind of electrical device that changes an AC voltage or a current value by using an electromagnetic induction phenomenon. There are various types of transformers depending on constants, the number of turns, cooling media, cooling methods, methods of preventing insulating oil deterioration, purposes, and the like.

In particular, such transformers mainly include cores, coils, insulating paper, and insulating materials and are classified according to frequency bands into low-frequency transformers that use the common frequency (60 Hz) and intermediate-high frequency transformers that use intermediate frequencies (60 to 1000 Hz) or high frequencies (1 to 200 kHz).

As the frequency is increased, the core, the coil, the insulating paper, and the insulating material constituting a transformer is affected by electromagnetic interference due to a strong magnetic field generated by the high frequency applied to the transformer, so that the efficiency of the transformer may not be maximized. For example, in a frequency band of 400 Hz to 50 kHz, the number of times that a period is repeated per a second is 400 to 50,000. Therefore, since a strong magnetic field is formed, electrons in the conductors of wires, electrodes, and the like are affected by electromagnetic interference due to the high frequencies, and thus the electrons in the core, the coil, the insulating paper, and the insulating material constituting the transformer are moved at a higher speed with a greater force. In this case, a phenomenon in which the electrons that originally have to flow into the conductors are abandoned in an unpredictable part by too high speed and force occurs. The abandoned electrons cause collisions with other electrons abandoned in different direction and generate heat (eddy current and magnetic hysteresis losses). And, in the case where the insulating material has a high permittivity and a weak insulation state, flashover and creeping discharge occur between coil layers and between the core and the coil.

When there are a large number of abandoned electrodes consumed by heat in the transformer itself, the amount of electrons (current) supplied to the load is reduced by the abandoned electrons consumed by the heat, and the voltage supplied to the load is increased by the amount of the reduced electrons (current). The load to which a small amount of electrons (current) and a high voltage are supplied generates high heat as time passes. When this phenomenon continues, the transformer that supplies the electrons and the voltage generates higher heat and causes flashover or creeping discharge (corona discharge), resulting in insulation breakdown.

The transformer according to the related art has problems as described above and thus has extremely low efficiency. In addition, such a transformer with a low efficiency has a large number of abandoned electrons and thus has a small amount of electrons supplied to the load (an electrode or a dielectric), so that a phenomenon of resonance (or tuning) with the load (the electrode or the dielectric) may not be generated.

In the transformer and a condenser-type load, the resonance phenomenon occurs as the L value of the transformer and the C value of the load are coincident with each other at a certain frequency. Here, the certain frequency at the coincident point is referred to as a resonance frequency. In order for the transformer to achieve an optimal efficiency in the load, the L value and the C value have to reach a certain coincident point by the resonance frequency. In order to generate the resonance (or tuning), the amount of electrons supplied from the transformer to the load has to be significantly increased compared to that according to the related art, and the transformer has to have no problem even with the electromagnetic interference due to the resonance frequency. The transformer manufactured in a design method of the transformer according to the related art may not generate resonance (or tuning) with the load as a higher frequency is applied. This is because the transformer is affected by the electromagnetic interference due to the resonance frequency since the insulating paper and the insulating material have high permittivities and the insulation state is weak, and thus the amount of electrons abandoned outside the transformer is increased, and eddy current and hysteresis losses are increased, so that the amount of electrons supplied to the load is rapidly reduced.

Therefore, a transformer which is not affected by electromagnetic interference due to frequencies in designing of the transformer and has a high efficiency needs to be manufactured. For this, the fact that electromagnetic interference due to frequencies is influenced by the permittivities and insulation rates of the constituent materials of the transformer, that is, a core, a coil, an insulating paper, and an insulating material has to be understood, and design on the basis of the correlations therebetween is needed.

### DISCLOSURE

### Technical Problem

The present invention has been made taking the foregoing problems of the transformer according to the related art into consideration and solving the problems, an object of which is to provide a transformer with low eddy current and magnetic hysteresis losses capable of minimizing electromagnetic interference affected by high frequencies and thus preventing a high heat and an insulation breakdown phenomenon which occur in the transformer through appropriate selection and designing of a core, a coil, an insulating paper, and an insulating material which are main constituent elements of the transformer, and a manufacturing method thereof.

Another object of the present invention is to provide a transformer with low eddy current and magnetic hysteresis losses capable of maximizing a transformer efficiency by oscillating a sine wave through a phenomenon of resonance (or tuning) with a load and minimizing a high heat, condensation, and streamer of the load, and a manufacturing method thereof.

### Technical Solution

In order to accomplish the objects, according to the present invention, a transformer with low eddy current and magnetic hysteresis losses, includes: a core; a primary coil and a secondary coil; an insulating paper; and an insulating material, wherein the core is made of an amorphous material or ferrite, the insulating paper has a low permittivity and a high insulation rate, is not subjected to impregnation with varnish or oil regardless of an insulation class, and is pure paper other than a synthetic paper, the insulating material is an epoxy or silicone resin with a low permittivity and a high insulation rate, an interlayer insulation thickness of the coil is maintained to be greater than 1 mm and smaller than 4 mm depending on a usage frequency, and an insulation interval between the core and the coil is maintained to be greater than 5 mm and smaller than 10 mm.

### Advantageous Effects

According to the transformer of the present invention, electrons abandoned from the core, the coil, the insulating paper, and the insulating material constituting the transformer may be minimized by the electromagnetic field generated by the frequency applied to the transformer.

In addition, a function of resonance (or tuning) with an electrode and a dielectric which are condenser-type loads is generated, the function not being supported by the transformer according to the related art, and a waveform close to the sine wave is generated by the transformer itself without an additional waveform compensation apparatus. Therefore, the transformer efficiency may be maximized, drive and maintenance costs of the transformer may be reduced, and the life span thereof may be increased.

### DESCRIPTION OF DRAWINGS

The above and other objects, features and advantages of the present invention will become apparent from the following description of certain exemplary embodiments given in conjunction with the accompanying drawings, in which:

FIG. 1 is a diagram illustrating the structure of a transformer according to the present invention, in which a primary coil and a secondary coil are arranged.

FIG. 2 is a structural diagram of an equivalent circuit of the transformer according to the present invention.

FIG. 3 is a perspective diagram of FIG. 1.

FIG. 4 is a diagram illustrating a molded state where, after the primary side coil and the first and second coils on the secondary side of FIG. 3 are wound, the coils are insulated by an epoxy resin or silicon.

FIG. 5 is an assembly perspective diagram of assembly of a coil-molded product in which the coils are insulated by the epoxy resin or silicon of FIG. 4 to a core.

### BEST MODE

Hereinafter, the embodiments of the present invention will be described in detail with reference to accompanying drawings.

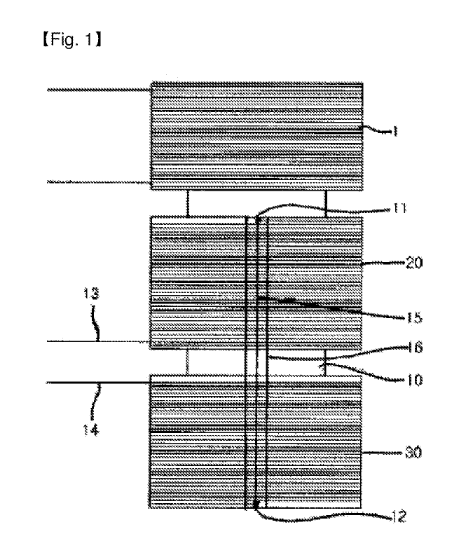

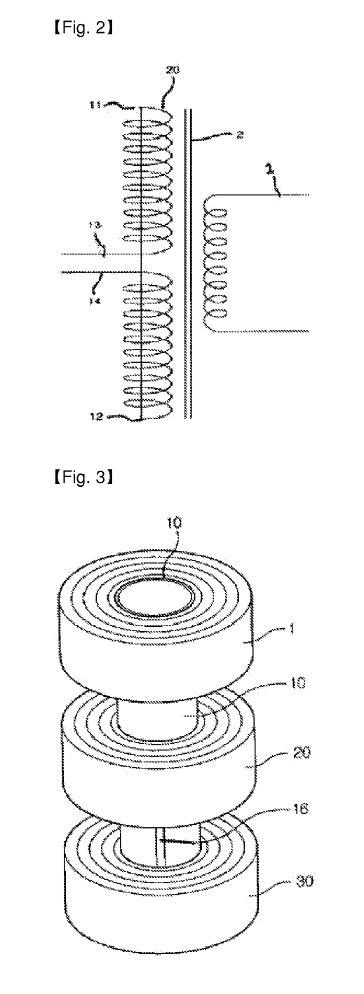

FIG. 1 is a diagram illustrating the structure of a transformer according to an embodiment of the present invention, in which a primary coil and a secondary coil are arranged, and FIG. 2 is a diagram showing an equivalent circuit of the transformer according to an embodiment of the present invention. FIG. 3 is a perspective view of FIG. 1.

The transformer includes a coil insulating paper 10, a primary side coil 1 wound around a first region of the coil insulating paper 10, a first coil 20 on a secondary side wound around a second region of the coil insulating paper 10, and a second coil 30 on the secondary side connected to the first coil 20 in series and wound around a third region of the coil insulating paper 10.

The first coil 20 is continuously connected from a start point 11 to an end point 13 so as to be wound around the second region of the coil insulating paper 10. The second coil 30 is continuously connected from a start point 12 to en end point 14 so as to be wound around the third region of the coil insulating paper 10. The starting points 11 and 12 of the first and second coils 20 and 30 are connected in series by soldering at both end points of a linear coil 15. The linear coil 15 is covered with pure paper which is an insulating paper, and thereafter the first and second coils 20 and 30 are wound around the linear coil 15. The end points 13 and 14 of the first and second coils 20 and 30 are connected to a load as voltage output ends. In FIG. 2, a core 2 is formed between the primary side coil 1 and the first and second coils 20 and 30 on the secondary side.

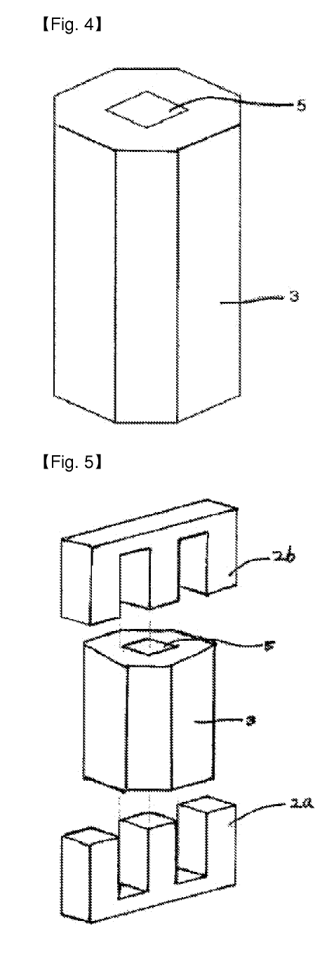

FIG. 4 is a diagram illustrating a molded state where, after the primary side coil 1 and the first and second coils 20 and 30 on the secondary side of FIG. 3 are wound, the coils are insulated by an epoxy resin or silicon, and FIG. 5 is an assembly perspective diagram of assembly of a coil-molded product 3 in which the coils are insulated by the epoxy resin or silicon of FIG. 4 to a core.

The core 2 is divided into first and second cores 2a and 2b. After the first core 2a is inserted into a hole 5 formed at the center of the coil-molded product 3, the second core 2b is fitted into the hole 5 formed at the center of the coil-molded product 3

The core 2 used in the present invention may be made of an amorphous material or ferrite for minimizing eddy current and magnetic hysteresis losses. Particularly, the amorphous material has excellent domain fluidity and thus is appropriate for an intermediate or high frequency transformer. As an alternative embodiment, a ferrite core which is large in size and is cheap may be used.

In addition, the thickness of the core and the number of turns used in the present invention vary depending on the frequency bands. In the case where the maximum output voltage is 10,000 V and the transformer capacity is 1000 VA, the thickness of the primary coil may be about 2 mm, the thickness of the secondary coil may be about 0.25 mm, the number of turns in the primary coil may be about 30, and the number of turns in the secondary coil may be about 1550.

Regarding the thicknesses of the primary and secondary coils, the above description are an example, and it is natural that the thicknesses of the primary and secondary coils according to a relationship between the maximum output voltage and the transformer capacity vary as in Table 1.

TABLE 1

| Maximum output | Transformer | Primary coil | Secondary coil |
|---|---|---|---|
| voltage | capacity (VA) | thickness (mm) | thickness (mm) |
| 10,000 V | 1,000 | 2.06 | 0.29 |
| | 500 | 1.45 | 0.20 |
| | 100 | 0.65 | 0.09 |
| 5,000 V | 1,000 | 2.06 | 0.41 |
| | 500 | 1.45 | 0.29 |
| | 100 | 0.65 | 0.13 |

Here, although it is desirable that the thicknesses of the primary coil 1 and the secondary coils 20 and 30 are exactly the same as the thicknesses shown in the above table, small deviations may be allowed.

Particularly, in the case where the output voltage of the secondary coil is higher than 5,000 V and lower than 10,000 V, in order to prevent insulation breakdown due to flashover between the core and the coil or between the coil interlayers or creeping discharge, the secondary coil may be sectioned into the first coil 20 and the second coil 30.

Sectioning is to provide a structure in which the secondary coil is divided into the first coil 20 and the second coil 30 which are in a state of being connected in series as in FIG. 1. In the embodiment of the present invention, the secondary coil is sectioned into two coils including the first and second coils 20 and 30. The sectioning of the coil may be division of the coil into two or more sections. For example, the secondary coil is wound as a single core when the output voltage thereof is 0 to 7 kV, the secondary coil may be sectioned into two coils when the output voltage thereof is higher than 7 kV and lower than 10 kV, the secondary coil may be sectioned into three coils when the output voltage thereof is higher than 10 kV and lower than 20 kV, the secondary coil may be sectioned into four coils when the output voltage thereof is higher than 20 kV and lower than 30 kV, and the secondary coil may be sectioned into five to ten coils when the output voltage thereof is equal to or higher than 30 kV depending on the voltage.

When the secondary coil is not divided, the voltage burden on the secondary coil is increased. In this case, even when a sufficient coil interlayer distance is provided by increasing the thickness of the insulating paper when a high frequency or a high voltage is applied, a large number of electrons penetrate the insulating paper and are excited on the outside due to electromagnetic interference. Therefore, heat is generated in the coil, and corona discharge occurs between the coils, so that the stability of the transformer is degraded.

On the other hand, when the secondary coil is divided into the first and second coils 20 and 30, the voltage is shared, and thus a voltage which is a burden on the coil is rapidly reduced. Therefore, the above-described phenomenon is suppressed, so that the stability of the transformer is enhanced.

As the insulating paper used in the present invention, an insulating paper may be used which is not subjected to impregnation with varnish or oil regardless of the insulation class and is pure paper other than a synthetic paper.

In the case of the insulating paper as shown in Table 2 which is mainly used for the transformer according to related art, the interlayer insulation thickness (0.2 to 0.3 mm) is small, and a synthetic paper to which an oil component is applied or which contains a film material is used in most of the transformers, and thus permittivity is high.

TABLE 2

| Insu- | Maximum | | |
|---|---|---|---|
| lating | allowable | | |
| paper | temperature | Main insulating material | Applied device |
| Y class | 90° C. | Cotton cloth, silk, aniline | Low-voltage |
| | | resin, and the like | device |
| A class | 105° C. | Varnish or oil-impregnated Y | Oil-filled |
| | | class paper, Kraft paper | transformer |
| E class | 120° C. | Polyurethane, cross-linked | Large-capacity |
| | | polyester resin | device |
| B class | 130° C. | Paper having mica, asbestos, | Mold transformer |
| | | or glass fiber used along with | |
| | | an adhesive, B class epoxy | |
| | | resin | |
| F class | 155° C. | Complex of B class and H | Mold transformer, |
| | | class such as silicone resin, | dry transformer |
| | | F class epoxy resin | |
| H class | 180° C. | Asbestos, glass fiber, silicone | H class dry |
| | | rubber, H class epoxy resin, | transformer, mold |
| | | Nomex paper | transformer |
| C class | 180° C. | Paper having mica, ceramic, | Special device |
| | or higher | glass, or the like used singly | requiring high |
| | | | temperature |

Here, representative examples are listed as the insulating paper, and as a matter of course, there are many kinds of insulating paper besides the examples.

The insulating material used according to the present invention is required to have a lowest permittivity and a high insulation rate so as to minimize an influence of electromagnetic interference due to the frequencies similarly to the insulating paper described above. Examples thereof may include an epoxy resin or a silicon-based insulating material. In an embodiment, as the epoxy resin, the epoxy resin-based adhesive 1500 manufactured and sold by Cemedine Co., Ltd. in Japan is used, and as the silicon insulating material, the KE1204 (ADB) which is the brand name manufactured and sold by Shin-Etsu Silicone Korea Co., Ltd. is used. In an embodiment, the silicon-based insulating material may be used in a high-frequency transformer, and the epoxy resin insulating material may be used in an intermediate-frequency transformer.

The transformer according to the present invention is manufactured as follows using the core, the coil, the insulating paper, and the insulating material selected under the above conditions.

First, when the core, the coil, the insulating paper, and the insulating material that coincide with the above-described conditions are selected, an operation of checking the usage conditions of the transformer is performed. Examples of the usage condition may include the power supply of an electrical device (load), a frequency range, power consumption, the transformer capacity, the input voltage and current of the primary coil, the maximum output voltage and current of the secondary coil, sectioning of the secondary coil during winding, the arrangement structure and the cooling structure, the winding method, and the maximum current limitation method.

The power supply may be referred to as single-phase/three-phase, 220V/380V, AC/DC, and the like. Most homes use a 60 Hz, single-phase, 220V power supply, and in industries, a 60 Hz, three-phase, 380V power supply is used.

Regarding the frequency range, the power consumption, and the transformer capacity, in the case where a transformer for an ozone generator or a plasma generator having a frequency range of 400 Hz to 50 kHz is manufactured, the maximum output voltage may be designed to be equal to or lower than 10,000 V which is in a range that does not strain the electrode and the dielectric, the maximum output current may be designed to be equal to or lower than 100 mA (0.1 A). Since the transformer capacity is obtained by the maximum output voltage×the maximum output current, the transformer capacity may be calculated as 1 KVA (10,000V×0.1 A). In the case of the input voltage and current of the primary coil, assuming that the maximum output voltage is 10,000 V, the maximum output current is 0.1 A, and a 60 Hz, single-phase, 220V power supply is used, the input voltage of the primary coil may be calculated as 220 V, and the input current may be calculated as 4.5 A (10,000 V×0.1 A=220 V×4.5 A).

Regarding the sectioning of the secondary coil, when the maximum output voltage exceeds 5000 V, the secondary coil may be sectioned as illustrated in FIG. 1 to prevent insulation breakdown. In addition, regarding the arrangement structure and the cooling structure, in the case of the present invention, heat is rarely generated. Therefore, for the convenience of operations, a shell-form or core-form arrangement structure is appropriate, and a natural cooling method may be used.

Regarding the winding method, a multiple-winding method may be used. This is because in the case of a single-winding method, an electromagnetic burden occurs when an electronic circuit (inverter) is configured and thus a breakdown frequently occurs.

Regarding the maximum current limitation method, when the maximum current is not limited, a strong magnetic flux is generated, and thus a breakdown occurs due to electromagnetic problems even in the electronic circuit (inverter) as well as the transformer. Therefore, according to the present invention, a 30% leakage type or a leakage-free type may be used.

As such, when the usage conditions needed for manufacturing the transformer according to the present invention are confirmed, an operation of cutting the insulating paper is performed.

The insulating paper cutting operation is an operation of cutting an insulating paper (with a low permittivity and a high insulation rate) which is not subjected to impregnation with varnish or oil and is pure paper other than a synthetic paper at predetermined intervals so as to be appropriate for the core. In the case where the maximum output voltage of the secondary coil exceeds 5000 V, a secondary winding portion has to be sectioned and thus the cross-sectional area of the insulating paper is reduced due to the sectioning. Therefore, in consideration of this, cutting may be performed.

When the insulating paper is cut through the operation, an operation of forming coil windings and an interlayer insulating portion is performed. Regarding the coil windings, as describe above, in the case of the primary coil, the interlayer insulation thickness of the coil may be maintained at 1 to 4 mm so as to coincide with a usage frequency range of the electrical device, the coil thickness may be set to about 2 mm. In addition, 8, 8, 7, and 7 turns, a total of 30 turns, may be wound around four respective layers in the first region of the coil insulating paper 10 as illustrated in FIG. 3, and the sum of the interlayer insulating paper thicknesses of the primary coil 1 may be set to be in the width of the core 2.

The reason that the coil interlayer insulation thickness is limited to be greater than 1 mm and smaller than 4 mm is that the interference of a corresponding use frequency has to be minimized and a voltage change rate has to be maintained to be equal to or lower than 2.0% that is determined by KS at a rated output. When the insulation thickness of the transformer having the frequency range of the present invention is smaller than 1 mm, the insulation function may not be performed. When the insulation thickness exceeds 4 mm, a resistance value is increased, and the voltage change rate becomes equal to or higher than 2.0%. Therefore, limitation of the insulation thickness to the above range is ideal in terms of the stability and efficiency of the transformer.

The thickness may be increased up to 60% of the insulation thickness at the maximum only if all the frequency, the transformer capacity, and the maximum output voltage use upper limit values. However, even in this case, when the thickness exceeds 60% at the maximum, a similar phenomenon occurs. Therefore, the thickness has to be limited to be equal to or lower than the numerical value. As a matter of course, the interlayer insulation thickness, the thickness of the coil, the number of turns, and the like as such are examples, and may be changed depending on the frequency or the transformer capacity.

In the case where the frequency range, the transformer capacity, and the maximum output voltage are increased higher than the above-mentioned values, the interlayer insulation thickness of the coil may be increased up to 20% of the insulation thickness. This is shown in Table 3.

TABLE 3

| | | Increase in interlayer |
|---|---|---|
| Classification | Reference | insulation thickness |
| Frequency | increase by 10 kHz | increase by 20% |
| Transformer capacity | increase by 1 kZA | increase by 20% |
| Maximum output voltage | increase by 1,000 V | increase by 20% |

Table 4 shows the interlayer insulation thicknesses of the coil depending on the frequency as an example. Here, it is assumed that the transformer capacity is 1 KVA (1000 VA). Therefore, it is natural that when this value is changed, the interlayer insulation thickness of the coil may be changed.

TABLE 4

| | Interlayer insulation |
|---|---|
| | thickness of coil |
| Frequency | (mm) |
| 400 Hz to 1 kHz | 1.0 |
| 1 kHz to 10 kHz | 1.0 to 2.0 |
| 10 kHz to 20 kHz | 2.0 to 2.5 |
| 20 kHz to 30 kHz | 2.5 to 3.0 |
| 30 kHz to 40 kHz | 3.0 to 3.5 |
| 40 kHz to 50 kHz | 3.5 to 4.0 |

In addition, regarding the secondary coil, the interlayer insulation thickness may be set on the basis of Table 4. The thickness thereof may be about 0.25 mm. 194,194,194, and 193 turns may be wound around each of the first and second coils 20 and 30 in the second and third regions of the coil insulating paper 10 as in FIG. 3, that is, 1,550 turns may be wound around a total of eight layers. In the case where the maximum output voltage of the secondary coil exceeds 5,000 V, the secondary coil may be sectioned for windings. Even in this case, as in the primary coil 1, it is natural that the above values may be changed depending on the frequency, the transformer capacity, and the like.

When the operation of forming the coil windings and the interlayer insulation portion through the operation is completed, an operation of forming the core 2 and a coil interlayer insulation portion (insulation interval) is performed.

The interlayer insulation interval between the core 2 and the coil may be greater than 5 mm and smaller than 10 mm and may be changed as the transformer capacity is changed. The reason that the insulation interval is limited to be greater than 5 mm and smaller than 10 mm is that in the case where the insulation interval is equal to or smaller than 5 mm, collision between the core magnetic flux and the coil-induced electrons may not be prevented and thus a high heat and insulation breakdown are induced, and in the case where the insulation interval is equal to or greater than 10 mm, the insulation function is not enhanced any more and only the insulation thickness is increased. Therefore, limitation of the insulation interval to the above range is ideal in terms of the stability and efficiency of the transformer.

The interlayer insulation interval between the core 2 and the coil may be easily checked by temporarily assembling the core 2 with the coil-molded product 3 in the state where the primary and secondary coils are wound and the formation of the insulation portion is completed, and the interlayer insulation interval may be accurately maintained using a measurement apparatus such as a gauge. Temporary assembly of the core 2 with the coil-molded product 3 includes inserting the first core 2a into the hole 5 formed at the center of the coil-molded product 3 and then inserting the second core 2b into the hole 5 formed at the center of the coil-molded product 3.

In the state where the core 2 and the coil-molded product 3 are temporarily assembled with each other, an electronic circuit (inverter) that may supply power at a predetermined frequency is connected to the input side of the transformer, and an electrical device is connected to the output side thereof so as to test the performance for output waveforms and the like.

When the interlayer insulation interval between the core 2 and the coil is finally ensured in this manner, an operation of removing moisture absorbed by the insulating paper in a vacuum state, and inserting the primary coil 1 and the first and second coils 20 and 30 of the secondary coil formed as in FIG. 3 into a molding die so as to be impregnated with an epoxy resin or silicon is performed.

The removing the moisture absorbed by the insulating paper is to minimize the permittivity that may be increased due to the moisture. The moisture may be evaporated through a heating unit, and the best method is always maintaining a condition where the transformer according to the present invention is manufactured in an environment having a humidity of 20 to 30% similar to the relative humidity in winter. When the primary coil 1 and the first and second coils 20 and 30 of the secondary coil formed as illustrated in FIG. 3 are inserted into the molding die, impregnated, and then cured, the coil-molded product 3 as in FIG. 4 is formed.

The insulating material such as an epoxy resin or silicon may be impregnated in the state where the primary side coil 1 and the first and second coils 20 and 30 of the secondary side coil are formed. The impregnation may be performed for a time longer than 4 hours and shorter than 48 hours. The reason that the time is limited is that impregnation is sufficiently achieved when the impregnation time is 4 or more hours and the impregnation efficiency is not increased when the impregnation time exceeds 48 hours. Therefore, this range is appropriate. Even in this case, as described above, the moisture of the insulating paper may be maintained to have a humidity of higher than 20% and lower than 30% similar to the relative humidity in winter.

When the impregnation with the epoxy resin or silicon is completed through the operation, a casing operation of producing an outer case to be used as the transformer through a performance test to cover the resultant is performed, thereby completing the manufacturing of the transformer.

The epoxy resin 1500 manufactured and sold by Cemedine Co., Ltd. in Japan and the KE1204 (ADB) which is the brand name manufactured and sold by Shin-Etsu Silicone Korea Co., Ltd. have low permittivities and high insulation rates as experimental results. According to the present invention, by using the epoxy resin or the silicon having a low permittivity and a high insulation rate as such, the coil-molded product having the primary coil 10 and the secondary coils 20 and 30 wound is manufactured. In an embodiment, the epoxy resin 1500 may be used in an intermediate-frequency or low-frequency transformer, and the KE1204 (ADB) which is the brand name manufactured and sold by Shin-Etsu Silicone Korea Co., Ltd. may be applied to a high-frequency transformer.

The reason that a humidity of higher than 20% and lower than 30% which is similar to the relative humidity in winter is maintained during the winding of the primary and secondary coils, the formation of the insulating portion, and the epoxy or silicon impregnation operation is that since the insulating paper and the insulating material have predetermined permittivities, moisture in the insulating paper and the insulating material further increases the permittivities under the influence of high frequencies and causes insulation breakdown in some cases. This may be easily understood by the fact that water having a predetermined permittivity is heated by several MHz in a microwave.

The transformer according to the present invention manufactured as described above is mainly characterized in that it is constituted by the core, the coils, the insulating paper, and the insulating material selected according to the usage conditions, and particularly, the coil interlayer insulation thickness is maintained at 1 to 4 mm and the interval between the core and the coil is maintained to be greater than 5 mm and smaller than 10 mm. In addition, the transformer is mainly characterized in the configuration in which the secondary coil is wound two or more turns to be sectioned in the case where the maximum output voltage of the secondary coil exceeds 5000 V.

### EXAMPLE

Hereinafter, examples according to the present invention will be described.

In order to check the characteristics of the transformer according to the present invention, a transformer was manufactured according to the manufacturing method of the present invention under the condition as shown in Table 3.

The example of related art is referred to as a transformer that has been used and the comparative example is referred to as a transformer of which a part of the condition is changed for comparison to the present invention.

TABLE 5

| | | | | | Insulation | Maximum |
|---|---|---|---|---|---|---|
| | | | Coil | | interval | output |
| | | Insulating | interlayer | | between | voltage of |
| | | paper | insulation | Transformer | core and | secondary |
| Classification | Frequency | class | thickness | capacity | coil | coil |
| Example of | 60 Hz | H class | 0.2 mm | 1 KVA | 1 mm | 2000 V |
| related art | | | | | | |
| Example of | 10 kHz | A class | 2.0 mm | 1 KVA | 10 mm | 2000 V |
| present | | | | | | |
| invention | | | | | | |
| Comparative | 10 kHz | A class | 0.8 mm | 1 KVA | 2 mm | 2000 V |
| example | | | | | | |

While the transformers manufactured under the conditions in Table 5 are used under the same condition, the characteristics of the transformers, for example, the amount of heat generated, no-load power loss, presence or absence of corona discharge, and presence or absence of flashover are checked, and the results are shown in Table 6.

TABLE 6

| | Amount of heat | No-load | Corona | |
|---|---|---|---|---|
| Classification | generated | power loss | discharge | Flashover |
| Example of related | 100° C. | 850 mA | Generated | Generated |
| art | | | | |
| Example of present | 18° C. | 20 mA | Absence | Absence |
| invention | | | | |
| Comparative | 90° C. | 100 mA | Generated | Generated |
| example | | | | |

As in Table 6, in the case of the example of the related art, the amount of heat generated, no-load power loss, and insulation breakdown (corona discharge and flashover) occur. In the case of the comparative example, although the eddy current and magnetic hysteresis losses are significantly reduced, it can be seen that the amount of heat generated is high, and insulation breakdown occurs due to corona discharge and flashover. However, in the case of the transformer according to the present invention, heat is rarely generated (at a level of the room temperature), and the no-load power loss is extremely small.

### INDUSTRIAL APPLICABILITY

As described above, according to the present invention, corona discharge and flashover rarely occur, so that insulation breakdown may be completely prevented, and thus the present invention may be used in all frequency bands including low-frequency, intermediate-frequency, and high-frequency bands. Particularly, the present invention may be appropriately used in a transformer mainly used in an ozone generator or a plasma generator.

1. A transformer with low eddy current and magnetic hysteresis losses, comprising:
a core;
a primary coil and a secondary coil;
an insulating paper; and
an insulating material,
wherein the core is made of an amorphous material or ferrite,
the insulating paper has a low permittivity and a high insulation rate, is not subjected to impregnation with varnish or oil regardless of an insulation class, and is pure paper other than a synthetic paper,
the insulating material is an epoxy or silicone resin with a low permittivity and a high insulation rate,
an interlayer insulation thickness of the coil is maintained to be greater than 1 mm and smaller than 4 mm depending on a usage frequency, and
an insulation interval between the core and the coil is maintained to be greater than 5 mm and smaller than 10 mm.

2. The transformer according to claim 1,
wherein the secondary coil is sectioned into a first coil and a second coil connected in series in a case where a maximum output voltage of the secondary coil is higher than 5,000 V and lower than 10,000 V.

3. The transformer according to claim 1,
wherein the interlayer insulation thickness of the coil is able to be increased only up to 60% of an upper limit of an insulation thickness in the case of the frequency, the transformer capacity, and the maximum output voltage.

4. A manufacturing method of a transformer with low eddy current and magnetic hysteresis losses, the method comprising:
setting transformer manufacturing conditions in which a core for the transformer is made of an amorphous material or ferrite, an insulating paper has a low permittivity and a high insulation rate, is not subjected to impregnation with varnish or oil regardless of an insulation class, and is pure paper other than a synthetic paper, an insulating material is an epoxy or silicone resin with a low permittivity and a high insulation rate, an arrangement structure has a shell-form or a core-form, a cooling method is a natural cooling method, a winding method is a multiple-winding method, a 30% leakage type or a leakage-free type is selected as a maximum current limitation method;
forming a coil interlayer insulation portion to form primary and secondary coil interlayer insulation portions to maintain insulation thicknesses of greater than 1 mm and smaller than 4 mm so as to be appropriate for a usage frequency after the selected insulating paper is cut, when the manufacturing conditions are set through the setting of the transformer manufacturing conditions;
forming an interlayer insulation portion between the core and a coil to form an interlayer insulation interval between the core and the coil to be greater than 5 mm and lower than 10 mm, after the primary and secondary coil interlayer insulation thicknesses are formed in the forming of the coil interlayer insulation portion;
removing moisture contained in the insulating paper in a state where a humidity of higher than 20% and lower than 30% which is similar to a relative humidity in winter so as to minimize the permittivity of the insulating paper is maintained, while maintaining the insulation interval formed in the forming of the interlayer insulation portion between the core and the coil so as to be greater than 5 mm and smaller than 10 mm;
manufacturing a coil-molded product through impregnation with the epoxy resin or silicon for a time longer than 4 hours and shorter than 48 hours in a state where the coil is formed, after the moisture of the insulating paper is removed; and
assembling the coil-molded product to the core after the coil-molded product is completed, testing performance of the assembly, and assembling an outer case, thereby manufacturing a product.

5. The method according to claim 4,
wherein the forming of the coil winding and interlayer insulation portion further includes sectioning the secondary coil into two ore more coils connected in series when a maximum output voltage of the secondary coil is higher than 5,000 V and lower than 10,000 V.

6. The transformer according to claim 2,
wherein the interlayer insulation thickness of the coil is able to be increased only up to 60% of an upper limit of an insulation thickness in the case of the frequency, the transformer capacity, and the maximum output voltage.
